(19) United States
(12) Patent Application Publication
(10) Pub. No.: US 2023/0387239 A1
(43) Pub. Date: Nov. 30, 2023

(54) SEMICONDUCTOR DEVICE INCLUDING GRAPHENE BARRIER AND METHOD OF FORMING THE SAME

(71) Applicant: TAIWAN SEMICONDUCTOR MANUFACTURING COMPANY, LTD., Hsinchu (TW)

(72) Inventors: Shin-Yi YANG, Hsinchu (TW); Meng-Pei LU, Hsinchu (TW); Han-Tang HUNG, Hsinchu (TW); Ching-Fu YEH, Hsinchu (TW); Ming-Han LEE, Hsinchu (TW); Shau-Lin SHUE, Hsinchu (TW)

(73) Assignee: TAIWAN SEMICONDUCTOR MANUFACTURING COMPANY, LTD., Hsinchu (TW)

(21) Appl. No.: 17/825,411

(22) Filed: May 26, 2022

(51) Int. Cl. H01L 29/45; H01L 29/06; H01L 29/423; H01L 29/786; H01L 29/775; H01L 21/02; H01L 21/285; H01L 29/40; H01L 29/66

(52) U.S. Cl. CPC H01L 29/45; H01L 29/0673; H01L 29/42392; H01L 29/78696; H01L 29/775; H01L 21/02603; H01L 21/28518; H01L 29/401; H01L 29/66742; H01L 29/66439

(57) ABSTRACT

A semiconductor device includes a substrate, a plurality of channel layers, two epitaxial structures, a conductive structure, a via, and a graphene barrier. The channel layers and the epitaxial structures are disposed over the substrate. The channel layers are connected between the epitaxial structures. The conductive structure is disposed on the substrate opposite to the epitaxial structures. The via is connected between one of the epitaxial structure and the conductive structure. The graphene barrier surrounds the via.

### BACKGROUND

Currently, semiconductor devices are widely used in various fields, such as cloud storage, medicine, transportation, mobile devices, etc. The current trend in some aspects of semiconductor device manufacturing focuses on providing semiconductor devices with smaller dimensions and better power efficiency. It is therefore desirable to continuously improve the structure and manufacturing of the semiconductor devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart illustrating a method of forming a semiconductor device in accordance with some embodiments.

FIGS. 2 to 15 show intermediate steps of a method of forming a semiconductor device in accordance with some embodiments.

FIG. 16 is a flow chart illustrating a method of forming a semiconductor device in accordance with some embodiments.

FIGS. 17 to 25 show intermediate steps of a method of forming a semiconductor device in accordance with some embodiments.

FIG. 26 is a flow chart illustrating a method of forming a semiconductor device in accordance with some embodiments.

FIGS. 27 to 31 show intermediate steps of a method of forming a semiconductor device in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. In addition, the term “source/drain” may refer to a source or a drain, individually or collectively dependent upon the context.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly,

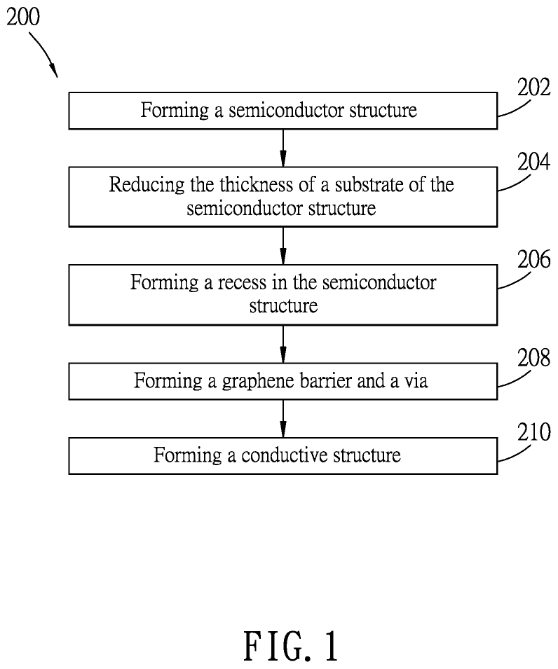

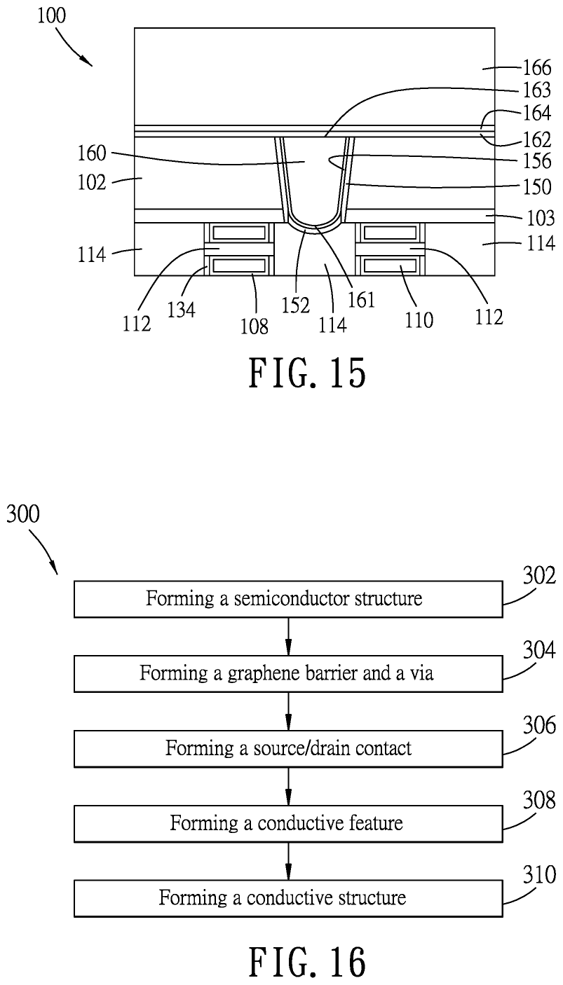

FIG. 1 illustrates a method 200 of forming a semiconductor device 100 (see FIG. 15), where a step 202 of the method 200 involves forming a semiconductor structure,

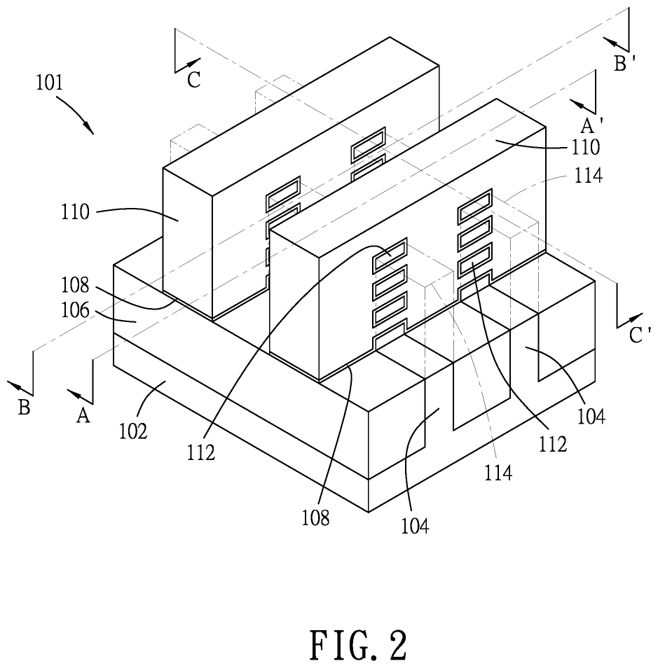

FIG. 2 shows a perspective view which is taken from an intermediate step of making the semiconductor structure 101 for illustration purposes, in accordance with some embodiments. The semiconductor structure 101 may be a nanowire field-effect transistor, nanosheet field-effect transistor, or other suitable types of transistors, in accordance with some embodiments. In some embodiments, the semiconductor structure 101 includes a substrate 102 which includes a plurality of fins 104 protruding upwardly.

In some embodiments, the semiconductor structure 101 further includes a plurality of isolation regions 106 that are disposed among the fins 104, a plurality of nanostructures 112 that are disposed over the substrate 102 and the fins 104, a plurality of gate dielectric layers 108 that are disposed over the substrate 102 and the fins 104 and that surround the nanostructures 112, a plurality of gate electrodes 110 that are disposed over the gate dielectric layers 108, and a plurality of epitaxial structures 114 that are respectively disposed over the fins 104 and that are connected to the nanostructures 112. (i.e., the nanostructures 112 are disposed between and connected to the epitaxial structures 114) and that are schematically shown by dotted lines so that the nanostructures 112 may be portrayed in FIG. 2.

FIG. 2 also illustrates referential cross-section lines that are described in detail in later figures. The cross-section line A-A′ extends along a longitudinal axis of one of the gate electrodes 110. The cross-section line B-B′ extends through the epitaxial structures 114 and parallel to the cross-section line A-A′. The cross-section line C-C′ extends through one of the fins 104 and is perpendicular to the cross-section lines A-A′ and B-B′.

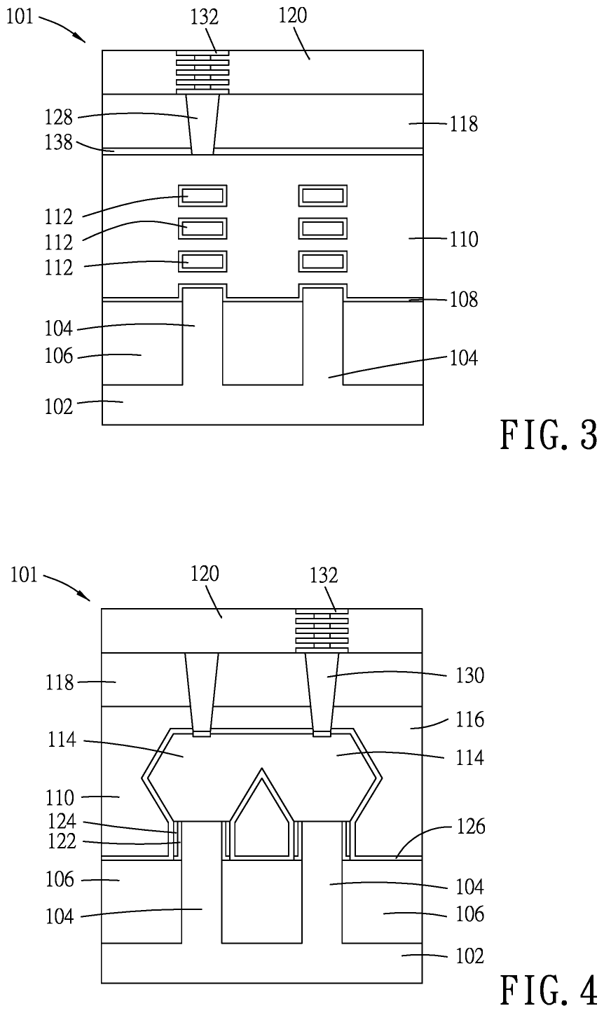

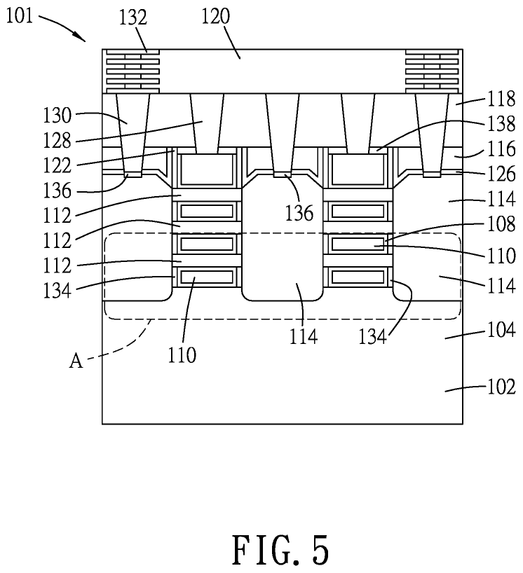

FIGS. 3 to 5 are schematic sectional views of the semiconductor structure 101 respectively taken from cross-section lines A-A′, B-B′, C-C of FIG. 2, where the figures only show parts of the semiconductor structure 101 (e.g., only two of the fins 104 are shown in FIGS. 3 and 4, and only three of the epitaxial structures 114 are shown in FIG. 5) for simplicity. In FIG. 4, the epitaxial structures 114 are illustrated as merged together according to some embodiments; however, in other embodiments, the epitaxial structures 114 may be separated from each other. Referring to FIGS. 3 to 5, in some embodiments, the semiconductor structure 101 further includes a first dielectric layer 116 that is disposed over the substrate 102, a second dielectric layer 118 that is disposed over the first dielectric layer 116, and a third dielectric layer 120 that is disposed over the second dielectric layer 118, where the epitaxial structures 114 and the gate electrodes 110 are disposed in the first dielectric layer 116. In some embodiments, the semiconductor structure 101 further includes a plurality of inner spacers 134 (see FIG. 5) that are connected to side walls of the gate dielectric layers 108 around the gate electrodes 110. In some embodiments, the semiconductor structure 101 further includes a plurality of first and second spacers 122, 124 that are disposed in the first dielectric layer 116 and that surround lower portions of the epitaxial structures 114. In some embodiments, the semiconductor structure 101 further includes a contact etch stop layer 126 that is disposed in the first dielectric layer 116 and around the epitaxial structures 114. In some embodiments, the semiconductor structure 101 further includes a plurality of gate masks 138 that are disposed in the first dielectric layer 116, and over the gate electrodes 110. In some embodiments, the semiconductor structure 101 further includes a plurality of gate contacts 128 that are disposed in the second dielectric layer 118, and that are connected to the gate electrodes 110. In some embodiments, the semiconductor structure 101 further includes a plurality of source/drain contacts 130 that are disposed in the first and second dielectric layers 116, 118, and that are connected to the epitaxial structures 114. In some embodiments, the semiconductor structure 101 further includes a plurality of silicide structures 136 that are connected between the epitaxial structures 114 and the source/drain contacts 130. In some embodiments, the semiconductor structure 101 further includes a plurality of conductive features 132 that are disposed in the third dielectric layer 120, and that are connected to the gate contacts 128 and/or the source/drain contacts 130. In some embodiments, the conductive features 132 may be a part of a back-end-of-line (BEOL) interconnect structure.

In some embodiments, the substrate 102 may be a suitable substrate, such as an elemental semiconductor or a compound semiconductor. The elemental semiconductor may contain a single species of atom, such as Si Ge or other suitable materials, e.g., other elements from column XIV of the periodic table. The compound semiconductor may be composed of at least two elements, such as GaAs, SiC, SiGe, GaP, InSb, InAs, InP, GaAsP, GainAs, AlGaAs, AlInAs, GaInAsP, or the like. In some embodiments, the composition of the compound semiconductor including the aforesaid elements may vary by having one ratio at one location and another ratio at a different location (i.e., the compound semiconductor may have a gradient composition). In some embodiments, the substrate 102 may be a semiconductor-on-insulator (SOI) substrate, such as silicon germanium-on-insulator (SGOT) substrate, or the like. In some embodiments, an SOT substrate may include an epitaxially grown semiconductor layer, such as Si, Ge, SiGe, any combination thereof, or the like, which is formed over an oxide layer. In some embodiments, each of the nanostructures 112 may be made of silicon, silicon germanium, silicon carbide, other suitable materials, or any combination thereof, and may be made by chemical vapor deposition (CND), atomic layer deposition (ALD), other suitable techniques, or any combination thereof. In some embodiments, the inner spacers 134 may be made of silicon oxide, silicon nitride, silicon oxynitride, other suitable materials, or any combination thereof, and may be made by CVD, ALD, other suitable techniques, or any combination thereof. In some embodiments, the isolation regions 106 may be made of an insulating material, such as silicon oxide, or other suitable materials, and may be made by CVD, or other suitable techniques, in some embodiments, each of the first, second, and third dielectric layers 116, 118, 120 may be made of SiOx, SiOxCy, SiOxCyHz, SiCx, SiNx, other suitable materials, or any combination thereof, and may be made by CVD, other suitable techniques, or any combination thereof. In some embodiments, each of the epitaxial structures 114 may be made of silicon, silicon carbide, silicon phosphide, other suitable materials, or any, combination thereof, and may be made by CVD, ALD, vapor phase epitaxy (VPE), molecular beam epitaxy (MBE), other suitable techniques, or any combination thereof. In some embodiments, each of the first and second spacers 122, 124 may be made of silicon oxide, silicon nitride, silicon oxynitride, other suitable materials, or any combination thereof, and may be made by CVD, ALD, other suitable techniques, or any combination thereof. In some embodiments, the contact etch stop layer 126 may be made of silicon nitride, silicon oxide, silicon oxynitride, other suitable materials, or any combination thereof, and may be made by CVD, ALD, other suitable techniques, or any combination thereof. In some embodiments, the gate dielectric layers 108 may be made of a high-k dielectric material, such as a metal oxide or silicate of hafnium, aluminum, zirconium, lanthanum, manganese, barium, titanium, lead, other suitable materials, or any combination thereof, and may be made by CVD, ALD, other suitable techniques, or any combination thereof. In some embodiments, the gate electrodes 110 may be made of titanium nitride, titanium oxide, tantalum nitride, tantalum carbide, cobalt, ruthenium, aluminum, tungsten, other suitable materials, or any combination thereof, and may be made by physical vapor deposition (PVD), other suitable techniques, or any combination thereof. In some embodiments, the gate masks 138 may be made of silicon oxide, silicon nitride, silicon oxynitride, other suitable materials, or any combination thereof, and may be made by CVD, PVD, other suitable techniques, or any combination thereof. In some embodiments, the silicide structures 136 may be made of NiSi, TiSi, TiNiSi, TiSiGe, NiSiGe, TiNiSiGe, RuSi, CoSi, MoSi, PtSi, TaSi, WSi, CrSi, ZrSi, other suitable materials, or any combination thereof. In some embodiments, each of the source/drain and gate contacts 130, 128 may be made of Cu, Ni, Co, Ru, Ir, Al, Pt, Pd, Au, Ag, Os, Mo, W, other suitable materials, or any combination thereof, and may be made by CVD, ALD, PVD, plating (including electroplating, electroless plating, etc.), other suitable techniques, or any combination thereof. In some embodiments, the conductive features 132 may be made of Cu, Ni, Co, Ru, Ir, Al, Pt, Pd, Au, Ag, Os, Mo, W, other suitable materials, or any combination thereof, and may be made by CVD. ALD, PVD, plating (including electroplating, electroless plating, etc.), other suitable techniques, or any combination thereof.

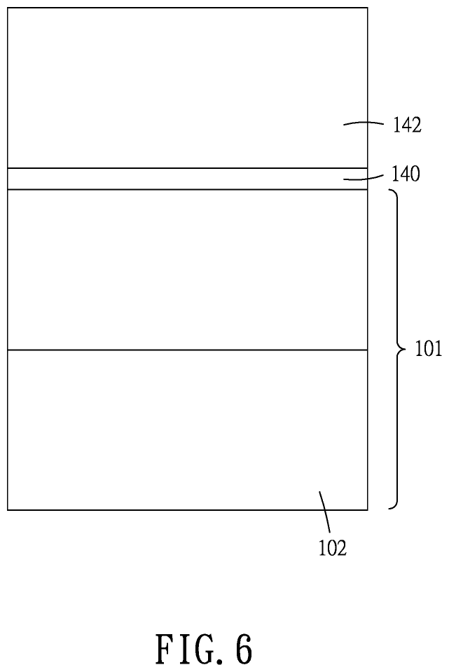

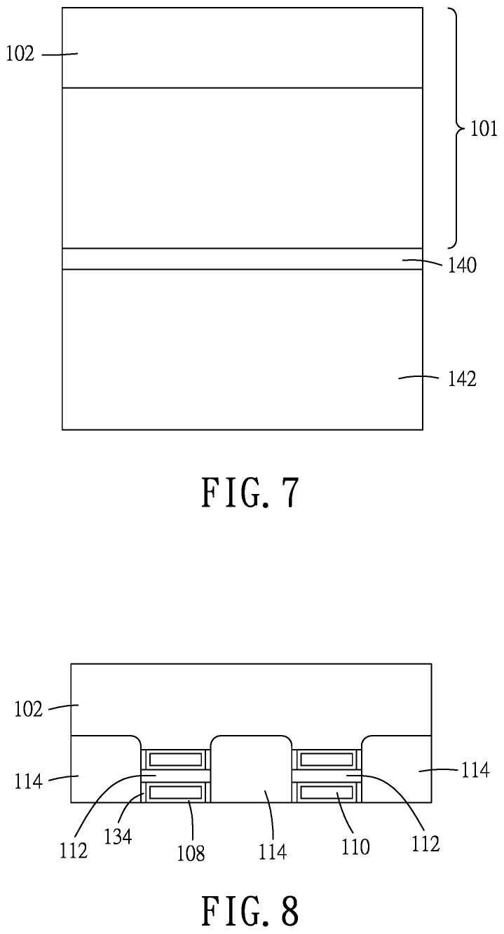

Referring to FIG. 1, in a step 204 of the method 200, the thickness of the substrate of the semiconductor structure is reduced. FIG. 6 schematically shows that the semiconductor structure 101 (e.g., the third dielectric layer 120 of the semiconductor structure 101 (see FIGS. 3 to 5)) is connected to a carrier substrate 142 via a bonding layer 140. In some embodiments, the carrier substrate 142 may be made of glass, ceramics, silicon, other suitable materials, or any combination thereof, and may provide structural support for subsequent processing steps. In some embodiments, the bonding layer 140 may be made of silicon oxide, other suitable materials, or any combination thereof, so that the carrier substrate 142 can be connected to the semiconductor structure 101 through dielectric-to-dielectric bonding, other suitable techniques, or any, combination thereof. Then, referring to FIG. 7, the carrier substrate 142 together with the bonding layer 140 and the semiconductor structure 101 may be flipped upside down, followed by reducing the thickness of the substrate 102 of the semiconductor structure 101 (see FIGS. 2 to 5) by grinding, chemical mechanical planarization (CMP), other suitable techniques, or any combination thereof.

Referring to FIG. 1, in a step 206 of the method 200, a recess is formed in the semiconductor structure. FIG. 8 is an enlarged view taken from block (A) of FIG. 5, after the thickness of the substrate 102 of the semiconductor structure 101 is reduced.

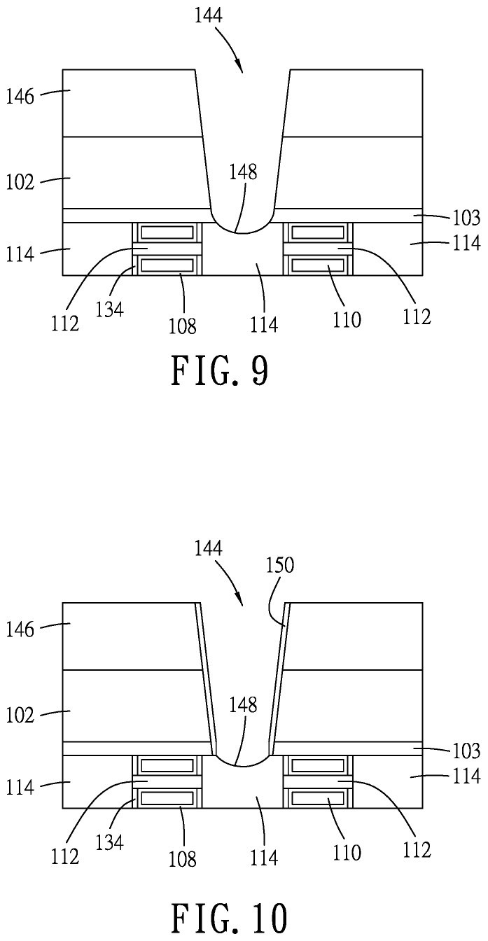

Then, referring to FIG. 9, a mask layer 146 is formed on the substrate 102, followed by patterning the mask layer 146 and the substrate 102 to form a recess 144, where a surface 148 of a corresponding one of the epitaxial structures 114 is exposed from the recess 144. In some embodiments, as illustrated by FIG. 9, a stop layer 103 may be provided to be located between the substrate 102 and the epitaxial structures 114, where the stop layer 103 may serve as an etch stop layer for the etching process of forming the recess 144. In some embodiments, the mask layer 146 may be made of an oxide-based material, a nitride-based material, a carbide-based material, other suitable materials, or any combination thereof, and may be made by CVD, PVD, other suitable techniques, or any combination thereof. In some embodiments, the mask layer 146 may be made of silicon nitride. In some embodiments, the recess 144 may be formed by plasma dry etch, other suitable techniques, or any combination thereof. In some embodiments, the recess 144 may have a circular or oval top view, but other suitable types of shapes are also possible.

Referring to FIG. 10, in some embodiments, a glue layer 150 may be formed in the recess 144 (e.g., formed on the sidewall defining the recess 144), followed by removing a part of the glue layer 150 so as to expose the surface 148 of the corresponding epitaxial structure 114. In some embodiments, the glue layer 150 may be made of an oxide-based material, a nitride-based material, a carbide-based material, other suitable materials, or any combination thereof, and may be made by CVD, PVD, ALD, other suitable techniques, or any combination thereof. In some embodiments, a part of the glue layer 150 may be removing by plasma dry etch, other suitable techniques, or any combination thereof.

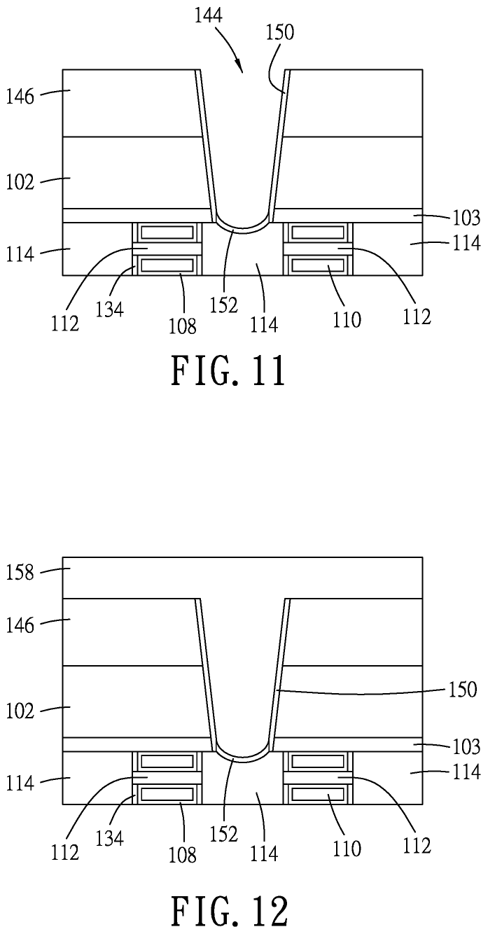

Referring to FIG. 1, in a step 208 of the method 200, a graphene barrier and a via are formed. Referring to FIG. 11, in some embodiments, a silicide feature 152 may be formed on the surface 148 of the corresponding epitaxial structure 114 (see FIG. 10). In some embodiments, the silicide feature 152 may be made of NiSi, TiSi, TiNiSi, TiSiGe, NiSiGe, TiNiSiGe, RuSi, CoSi, MoSi, PtSi, TaSi, WSi, CrSi, ZrSi, other suitable materials, or any combination thereof. In some embodiments, the silicide feature 152 may be formed by depositing a metal on the surface 148 of the corresponding epitaxial structure 114, followed by heating the metal so that the metal reacts with the corresponding epitaxial structure 114 to form the silicide feature 152.

Referring to FIG. 12, a filling conductive layer 158 may be formed to fill the recess 144 (see FIG. 11) and covers the mask layer 146. In some embodiments; the filling conductive layer 158 may be made of Cu, Ni, Co, Ru, Ir. Al, Pt, Pd, Au, Age Os, Mo, W, other suitable materials, or any combination thereof, and may be made by CVD, ALD, PVD, other suitable techniques, or any combination thereof.

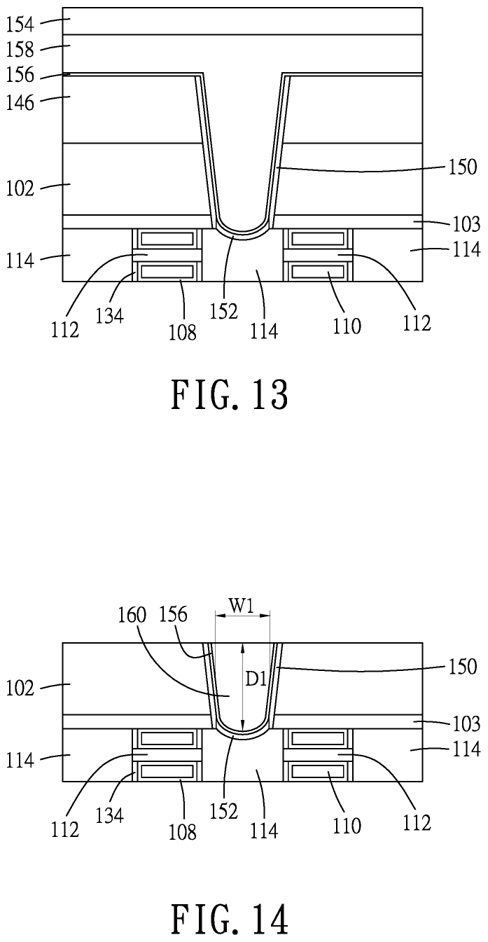

Referring to FIG. 13, a carbon-containing material 154 may be formed on the filling conductive layer 158. In some embodiments, the carbon-containing material 154 may serve as a carbon source for forming a graphene barrier 156 as shown in FIG. 13, and may be a solid, a liquid, a gas, or any combination thereof. In some embodiments, the carbon-containing material 154 may be made of graphite (e.g., graphite powder, graphite blocks, etc.), amorphous carbon (e.g., hydrocarbon compounds), other suitable materials, or any combination thereof. In some embodiments, the carbon-containing material 154 may be formed by CVD, AU) (with or without plasma enhancement), other suitable techniques, or any combination thereof. Then the carbon atoms of the carbon-containing material 154 are forced (e.g., by heating) to diffuse through the filling conductive layer 158 and crystalize underneath the filling conductive layer 158 into at least one layer of graphene to form the graphene barrier 156. In some embodiments, the carbon-containing material 154 may be heated under a temperature ranging from about 200° C. to about 1200° C., from about 200° C. to about 300° C., from about 300° C. to about 400° C., from about 400° C. to about 500° C., from about 500° C. to about 600 CC, from about 600° C. to about 700° C., from about 700° C. to about 800° C., from about 800° C. to about 900° C., from about 900° C. to about 1000° C., from about 1000° C. to about 1100° C., from about 1100° C. to about 1200° C., or may be in other suitable ranges. In some embodiments, if the temperature of heating the carbon-containing material 154 is too low, such as lower than about 200° C., the carbon atoms of the carbon-containing material 154 may not diffuse through the filling conductive layer 158. In some embodiments, if the temperature of heating the carbon-containing material 154 is too high, such as higher than about 1200° C., the filling conductive layer 158 may melt and the high temperature may adversely affect the epitaxial structures 114.

In some embodiments, the carbon-containing material 154 may be pressurized, or both heated and pressurized to form the graphene barrier 156. In some embodiments, the graphene barrier 156 may contain layers of pure graphene. In other embodiments, during formation of the carbon-containing material 154 and/or heating/pressurizing the carbon-containing material 154, oxygen-containing gases, nitrogen-containing gases, and intercalants may be introduced to respectively form graphene oxide, graphene nitride, and intercalated graphene. In some embodiments, the intercalants may include metal, metal halide compounds, metal oxides, other suitable materials, or any combination thereof. In some embodiments, the intercalants may include Fe, Mo, W. Ag, Au, Ru, Co, FeCl₃, MoO₃, other suitable materials, or any combination thereof.

Referring to FIGS. 13 and 14, after forming the graphene barrier 156, the carbon-containing material 154, a part of the conductive layer 158, a part of the graphene barrier 156, the mask layer, and a part of the glue layer 150 may be removed to form the via 160 in the recess 144 (see FIG. 11). In some embodiments, the removing process may be conducted by plasma dry etch, chemical wet etch, CMP, other suitable techniques, or any combination thereof. In some embodiments, the via 160 may have a circular or oval top view, but other suitable shapes are also possible. In some embodiments, the via 160 may have a width (W1) ranging from about 5 nm to about 100 nm, from about 5 nm to about 10 nm, from about 10 nm to about 15 nm, from about 15 nm to about 20 nm, from about 20 nm to about 25 nm, from about 25 nm to about 30 nm, from about 30 nm to about 35 nm, from about 35 nm to about 40 nm, from about 40 nm to about 45 nm, from about 45 nm to about 50 nm, from about 50 nm to about 55 nm, from about 55 nm to about 60 nm, from about 60 nm to about 65 nm, from about 65 nm to about 70 nm, from about 70 nm to about 75 nm, from about 75 nm to about 80 nm, from about 80 nm to about 85 nm, from about 85 nm to about 90 nm, from about 90 nm to about 95 nm, from about 95 nm to about 100 nm, or may be in other suitable ranges. In some embodiments, if the width (W1) of the via 160 is too small, such as smaller than about 5 nm, it may be difficult for the conductive layer 158 to fill the recess 144 (see FIG. 11) and defects (e.g., voids) may be formed in the via 160. In some embodiments, if the width (W1) of the via 160 is too large, such as greater than about 100 nm, the via 160 may occupy a large area of the substrate 102, reducing routing density of the semiconductor device 100. In some embodiments, the via 160 may have a depth (D1) ranging from about 10 nm to about 200 nm, from about 10 nm to about 20 nm, from about 2.0 nm to about 30 nm, from about 30 nm to about 40 nm, from about 40 nm to about 50 nm, from about 50 urn to about 60 urn, from about 60 nm to about 70 nm, from about 70 nm to about 80 nm, from about 80 nm to about 90 nm, from about 90 urn to about 100 nm, from about 100 nm to about 110 nm, from about 110 nm to about 120 nm, from about 120 nm to about 130 nm, from about 130 nm to about 140 nm, from about 140 nm to about 150 nm, from about 150 nm to about 160 nm, from about 160 nm to about 170 nm, from about 170 nm to about 180 nm, from about 180 nm to about 190 nm, from about 190 nm to about 200 nm, or may be in other suitable ranges. In some embodiments, if the depth (D1) of the via 160 is too small, such as smaller than about 10 nm, the substrate 102 must be ground thinner to have a smaller thickness, which may be difficult to do and may introduce defects to the substrate 102. In some embodiments, if the depth (D1) of the via 160 is too large, such as greater than about 200 nm, it may be difficult for the conductive layer 158 to fill the recess 144 (see FIG. 11) and defects (e.g., voids) may be formed in the via 160.

Referring to FIG. 1, in a step 210 of the method 200, a conductive structure is formed. Referring to FIG. 15, the conductive structure 166 may be formed on the substrate 102 and connected to the via 160, thereby obtaining the semiconductor device 100. In some embodiments, prior to forming the conductive structure 166, a barrier layer 162 and/or a liner layer 164 may be formed on the substrate 102 for promoting adhesion of the conductive structure 166 to the substrate 102 and preventing molecules of the conductive structure 166 from diffusing into the semiconductor device 100. In some embodiments, the barrier layer 162 may be made of a nitride-based material (e.g., TiN, TaN, etc.), other suitable materials, or any combination thereof, and may be formed by ALD, CVD, PVD, other suitable techniques, or any combination thereof. In some embodiments, the liner layer 164 may be made of Co, Ta, Ru, other suitable materials, or any combination thereof, and may be formed by ALD, CVD, PVD, other suitable techniques, or any combination thereof. In some embodiments, the conductive structure 166 may include multiple layers of conductive vias and conductive wires, according to practical requirements.

Referring to FIGS. 2 to 5 and 15, in some embodiments, the semiconductor device 100 includes the substrate 102, a plurality of the nanostructures 112 that are formed over the substrate 102, at least one of the gate electrodes 110 that is disposed over the substrate 102 and around the nanostructures 112 where the nanostructures 112 are separated from the gate electrode 110 by the gate dielectric layers 108, at least two of the epitaxial structures 114 that are disposed over the substrate 102 and that are connected between the nanostructures 112 where the nanostructures 112 may serve as channel layers 112 for transmission of carriers between the epitaxial structures 114, a plurality of the conductive features 132 that are connected to the epitaxial structures 114, the via 160 that is disposed in the substrate 102 and that is connected to the corresponding one of the epitaxial structures 114, and the graphene barrier 156 that is disposed between the via 160 and the substrate 102, disposed between the via 160 and the corresponding epitaxial structure 114, and that surrounds the via 160. In some embodiments, the semiconductor device 100 may further include the conductive structure 166 that is disposed on the substrate 102 (e.g., disposed underneath the substrate 102) and that is connected to the conductive structure 166. In some embodiments, the via 160 includes a first surface 161 that is connected to the corresponding one of the epitaxial structures 114, and a second surface 163 that is opposite to the first surface 161 and that is connected to the conductive structure 166. The graphene barrier 156 covers the first surface 161 and is disposed outside of the second surface 163, In some embodiments, the semiconductor device 100 further includes the silicide feature 152 that is connected to the corresponding one of the epitaxial structures 114 and that is connected to a portion of the graphene barrier 156 which covers the first surface 161.

In some embodiments, the via 160 may be referred to as a backside via (VB), and the conductive structure 166 may be referred to as a first backside metal (BM0). The via 160 together with the conductive structure 166 may be a power rail for providing electric power to the corresponding epitaxial structure 114 that is connected to the via 160. In some embodiments, the graphene barrier 156 may improve adhesion of the via 160 to the substrate 102 and/or prevent molecules of the via 160 from diffusing out of the graphene barrier 156. In addition, in some embodiments, the graphene barrier 156 may prevent breakdown through the graphene barrier 156, thereby improving time-dependence-dielectric-breakdown (TDDB) performance of the semiconductor device 100. In some embodiments, the graphene barrier 156 may have a thickness ranging from about 1 Å to about 20 Å, from about 1 Å to about 5 Å, from about 5 Å to about 10 Å, from about 10 Å to about 15 Å, from about 15 Å to about 20 Å, or may be in other suitable ranges. In some embodiments, if the thickness of the graphene barrier 156 is too small, such as smaller than about 1 Å, the graphene barrier 156 may not be properly formed (i.e., the graphene may not be formed properly) and/or the graphene barrier 156 may not be able to prevent the molecules of the conductive structure 166 from diffusing out of the graphene barrier 156. In some embodiments, if the thickness of the graphene barrier 156 is too large, such as greater than about 20 Å, the graphene barrier 156 may occupy a large portion of the recess 144, causing the via 160 to have a smaller volume and higher resistivity. In some embodiments, due to the relative thin graphene barrier 156, the via 160 can be made to have a greater volume and lower resistivity. In addition, the point where the graphene barrier 156 is in contact with the silicide feature 152 has a low resistance (i.e., a reduced contact resistance of the silicide feature 152). With the increased volume of the via 160 and reduced contact resistance of the silicide feature 152, the power performance of the semiconductor device 100 may be improved and undesirable issues, such as current-resistance (IR) voltage drop may be alleviated.

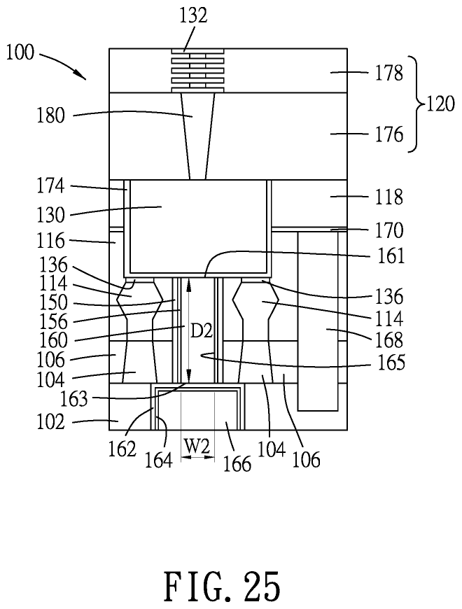

FIG. 16 illustrates a method 300 of forming the semiconductor device 100 (see FIG. 25) in accordance with some embodiments of this disclosure. In a step 302 of the method, the semiconductor structure is formed,

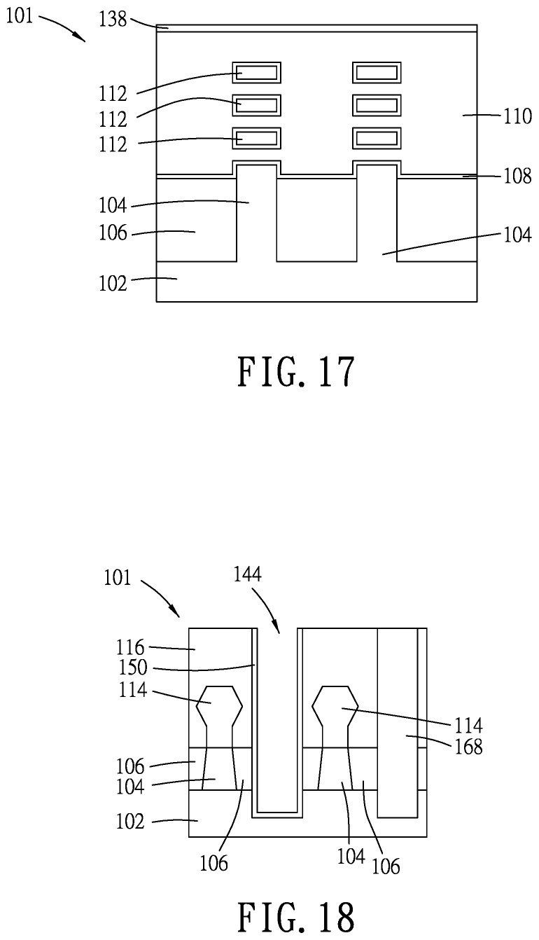

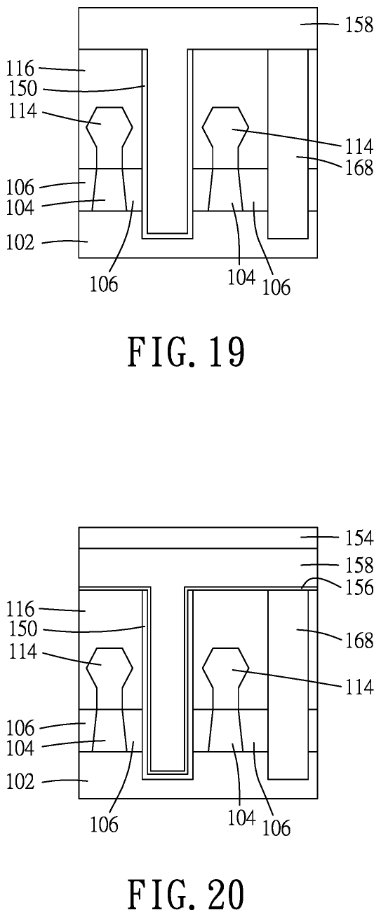

FIGS. 17 and 18 are schematic sectional views similar to FIGS. 3 and 4 (respectively taken from cross-section lines A-A′ and B-B′ of FIG. 2). In accordance with the embodiments shown by FIGS. 2, 17 and 18, the semiconductor structure 101 includes the substrate 102 which includes a plurality of the fins 104 protruding upwardly, a plurality of the isolation regions 106 disposed among the fins 104, the first dielectric layer 116 that is disposed over the substrate 102, a plurality of the nanostructures 112 that are disposed over the substrate 102 and the fins 104, a plurality of the gate dielectric layers 108 that are disposed over the substrate 102 and the fins 104 and that surround the nanostructures 112, a plurality of the gate electrodes 110 that are disposed over the gate dielectric layers 108, a plurality of the epitaxial structures 114 that are disposed in the first dielectric layer 116, that are respectively disposed over the fins 104 and that are connected to the nanostructures 112, a plurality of the gate masks 138 that are disposed in the first dielectric layer 116 and over the gate electrodes 110. In some embodiments, at least two of the epitaxial structures 114 along the cross-section line B-B′, as shown in FIG. 18, are separated from each other. In some embodiments, the semiconductor structure 101 may further include at least one isolation structure 168 that is formed in the first dielectric layer 116, a corresponding one of the isolation regions 106 and the substrate 102 for isolating the epitaxial structures 114.

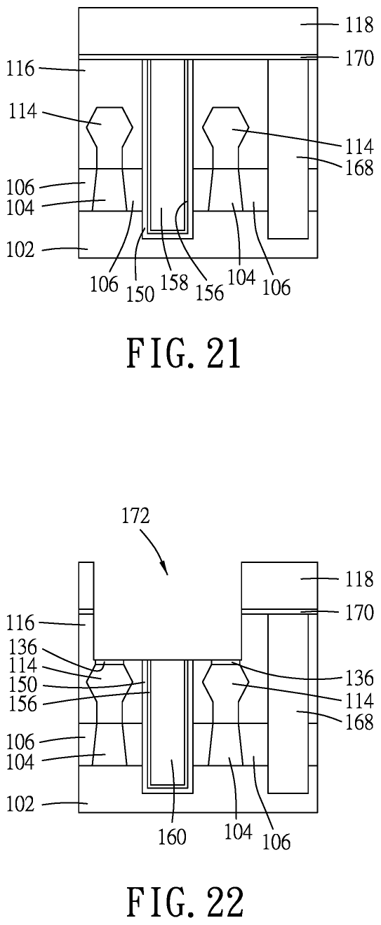

Referring to FIG. 16, in a step 304 of the method 300, the graphene barrier and the via are formed. Referring to FIG. 18, in some embodiments, the recess 144 may be formed in the first dielectric layer 116, a corresponding one of the isolation regions 106, and the substrate 102, and then the glue layer 150 may be formed in the recess 144. Then, referring to FIG. 1c, the filling conductive layer 158 is formed in the recess 144 (see FIG. 18) and over the first dielectric layer 116, in accordance with some embodiments. Then, referring to FIG. 20, the carbon-containing material 154 is formed over the filling conductive layer 158, followed by heating and/or pressurizing the carbon-containing material 154 to form the graphene barrier 156 in accordance with some embodiments. Then, referring to FIG. 21, the carbon-containing material 154, a part of the filling conductive layer 158, and a part of the graphene barrier 156 are removed, followed by forming an etch stop layer 170 over the first dielectric layer 116, and the second dielectric layer 118 over the first dielectric layer 116 and the etch stop layer 170, in accordance with some embodiments. Afterwards, a trench 172 is formed by removing a part of the second dielectric layer 118, a part of the etch stop layer 170, a part of the first dielectric layer 116, a part of the filling conductive layer 158, and a part of the graphene barrier 156, thereby exposing the epitaxial structures 114.

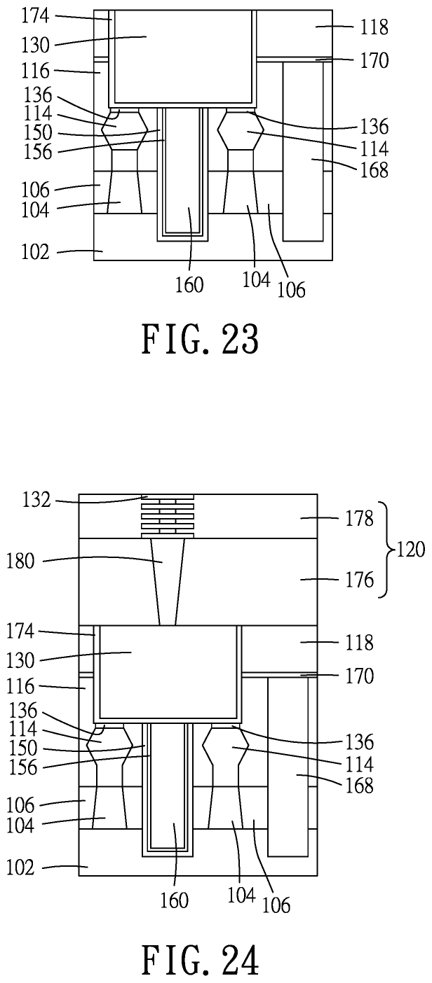

Referring to FIG. 16, in a step 306 of the method 300, the source/drain contact is formed. Referring to FIG. 22, in some embodiments, the silicide structures 136 may be respectively formed on the epitaxial structures 114 exposed from the trench 172. Then, referring to FIG. 23, the source/drain contact 130 is formed in the trench 172 (see FIG. 22), is connected to the epitaxial structures 114 via the silicide structures 136, and is connected to the via 160. In some embodiments, a barrier/liner layer 174 may be formed in the trench 172 to surround the source/drain contact 130. In some embodiments, the barrier/liner layer 174 may be made of a nitride-based material (e.g., TiN, TaN, etc.), other suitable materials, or any combination thereof. In some embodiments, the source/drain contact 130 shown in FIG. 23 may be referred to as MD (metal over diffusion). In some embodiments, the via 160 may be connected to a conductive metal (not shown) that is connected to a corresponding one of the gate electrodes 110 (see FIG. 2).

Referring to FIG. 16, in a step 308 of the method 300, the conductive feature is formed. Referring to FIG. 24, in some embodiments, the third dielectric layer 120 may be formed over the second dielectric layer 118, followed by forming the conductive feature 132 that is disposed in the third dielectric layer 120 and that is connected to the source/drain contact 130. In some embodiments, the third dielectric layer 120 may include a first sub-layer 176 that is disposed over the second dielectric layer 118, and a second sub-layer 178 that is disposed over the first sub-layer 176. In some embodiments, the conductive feature 132 disposed in the second sub-layer 178 may be connected to the source/drain contact 130 via a contact feature 180 which is disposed in the first sub-layer 176.

Referring to FIG. 16, in a step 310 of the method 300, the conductive structure is formed. Referring to FIG. 25, the conductive structure 166 may be formed in the substrate 102 and connected to the via 160, thereby obtaining the semiconductor device 100. In some embodiments, a part of the glue layer 150, a part of the graphene barrier 156 and a part of the via 160 may be removed before forming the conductive structure 166. In some embodiments, prior to forming the conductive structure 166, the barrier layer 162 and/or the liner layer 164 may be formed on the substrate 102. In some embodiments, the via 160 includes the first surface 161 that is connected to the source/drain contact 130, the second surface 163 that is opposite to the first surface 161 and that is connected to the conductive structure 166, and a side surface 165 that is connected between the first and second surface 161, 163. The graphene barrier 156 covers the side surface 165, and is disposed outside of the first and second surfaces 161, 163. In some embodiments, the source/drain contact 130 and the conductive structure 166 are disposed opposite to each other relative to the epitaxial structures (114).

Referring to FIG. 25, in some embodiments, the via 160 may have a width (W2) ranging from about 5 nm to about 100 nm, from about 5 nm to about 10 nm, from about 10 nm to about 15 nm, from about 15 nm to about 20 nm, from about 20 nm to about 25 nm, from about 25 nm to about 30 nm, from about 30 nm to about 35 nm, from about 35 nm to about 40 nm, from about 40 nm to about 45 nm, from about 45 nm to about 50 nm, from about 50 nm to about 55 nm, from about 55 nm to about 60 nm, from about 60 nm to about 65 nm, from about 65 nm to about 70 nm, from about 70 nm to about 75 nm, from about 75 nm to about 80 nm, from about 80 nm to about 85 nm, from about 85 nm to about 90 nm, from about 90 nm to about 95 nm, from about 95 nm to about 100 nm, or may be in other suitable ranges. In some embodiments, if the width (W2) of the via 160 is too small, such as smaller than about 5 nm, it may be difficult for the conductive layer 158 to fill the recess 144 (see FIG. 18) and defects (e.g., voids) may be formed in the via 160. In some embodiments, if the width (W2) of the via 160 is too large, such as greater than about 100 nm, the via 160 may occupy a large area of the substrate 102, reducing routing density of the semiconductor device 100. In some embodiments, the via 160 may have a depth (D2) ranging from about 20 nm to about 300 nm, from about 20 nm to about 30 nm, from about 30 nm to about 40 nm, from about 40 nm to about 50 nm, from about 50 nm to about 60 nm, from about 60 nm to about 70 nm, from about 70 nm to about 80 nm, from about 80 nm to about 90 nm, from about 90 nm to about 100 nm, from about 100 nm to about 110 nm, from about 110 nm to about 120 nm, from about 120 nm to about 130 nm, from about 130 nm to about 140 nm, from about 140 nm to about 150 nm, from about 150 nm to about 160 nm, from about 160 nm to about 170 nm, from about 170 nm to about 180 nm, from about 180 nm to about 190 nm, from about 190 nm to about 200 nm, from about 200 nm to about 210 nm, from about 210 nm to about 220 nm, from about 220 nm to about 230 nm, from about 230 nm to about 240 nm, from about 240 nm to about 250 nm, from about 250 nm to about 260 nm, from about 260 nm to about 270 nm, from about 270 nm to about 280 nm, from about 280 nm to about 290 urn, from about 290 nm to about 300 nm, or may be in other suitable ranges. In some embodiments, if the depth (D2) of the via 160 is too small, such as smaller than about 20 nm, the height of the epitaxial structures 114 may need to be decreased, adversely affecting electric properties of the semiconductor device 100, In some embodiments, of the depth (D2) of the via 160 is too large, such as greater than about 300 nm, it may be difficult for the conductive layer 158 to fill the recess 144 (see FIG. 18) and defects (e.g., voids) may be formed in the via 160.

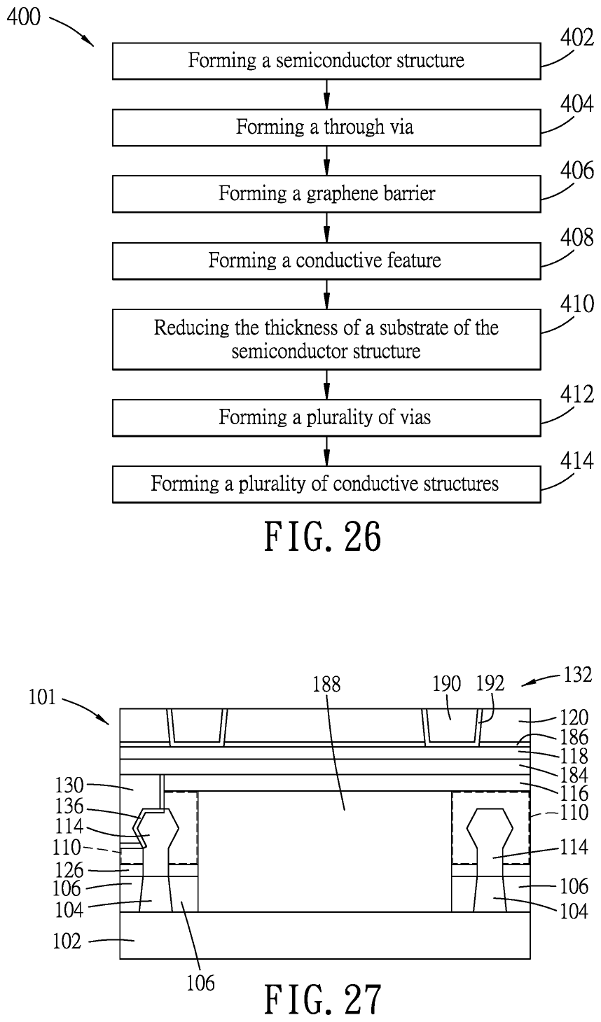

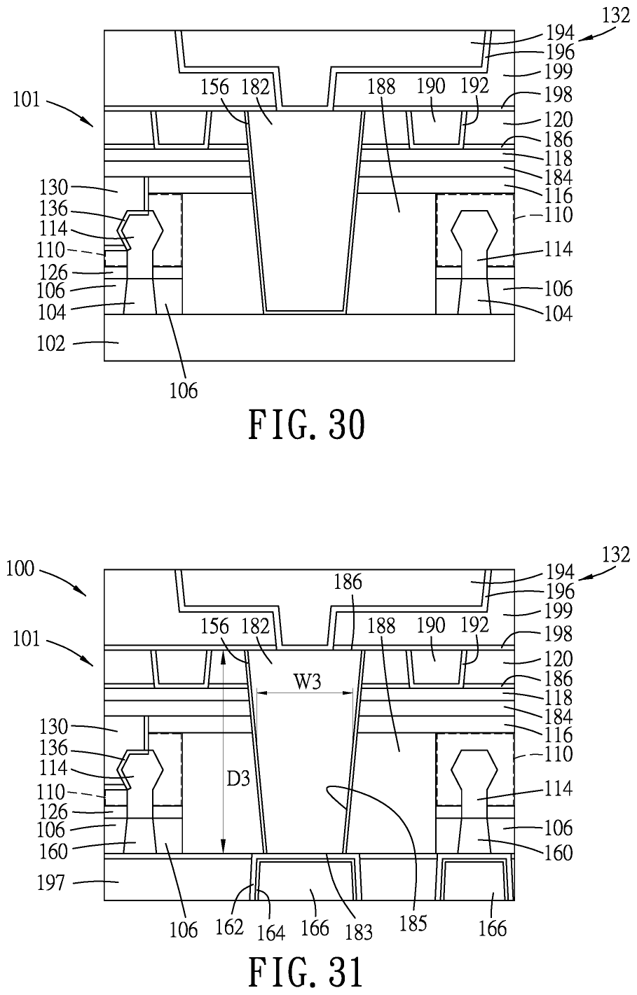

FIG. 26 illustrates a method 400 of forming the semiconductor device 100 (see FIG. 30) in accordance with some embodiments of this disclosure. In a step 402 of the method 400, the semiconductor structure is formed.

FIG. 27 is a schematic sectional view similar to FIG. 4 (taken from cross-section line B-B′ of FIG. 2). Of the embodiments shown in FIG. 27, the epitaxial structures 114 of the semiconductor structure 101 are separated from each other, and the gate electrodes 110 shown in FIG. 27 are separated by an isolation feature 188. In addition, the semiconductor structure 101 further includes a middle contact etch stop layer 184 that is disposed over the source/drain contact 130 and the first dielectric layer 116, and a first metal etch stop layer 186 that is disposed over the second dielectric layer 118. In some embodiments, the semiconductor structure 101 further includes a first conductive member 190 that is disposed in the third dielectric layer 120 and that is a part of the conductive feature 132. In some embodiments, the first conductive member 190 may be surrounded by a first conductive barrier/liner 192, and may be referred to as M0.

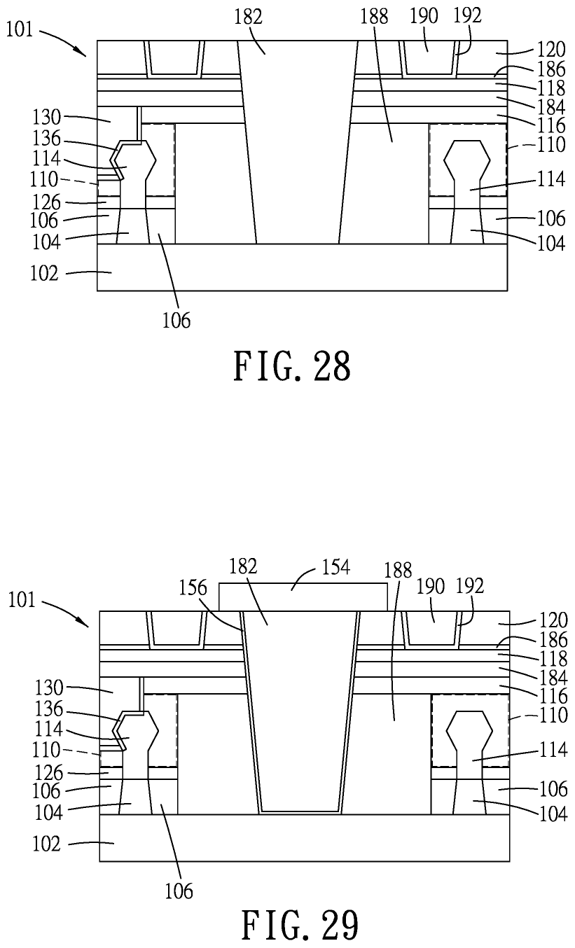

Referring to FIG. 26, in a step 404 of the method 400, a through via is formed. Referring to FIG. 28, in some embodiments, the through via 182 is formed in the isolation feature 188, the first dielectric layer 116, the middle contact etch stop layer 184, the second dielectric layer 118, the first metal etch stop layer 186, and the third dielectric layer 120. In some embodiments, the through via 182 penetrates the isolation feature 188. In some embodiments, the through via 182 may be made of Co, Ni, Ru, other suitable materials, or any combination thereof, and may be made by CVD, PVD, other suitable techniques, or any combination thereof.

Referring to FIG. 26, in a step 406 of the method 400, the graphene barrier is formed. Referring to FIG. 29, in some embodiments, the carbon-containing material 154 is formed over the through via 182, followed by heating and/or pressurizing the carbon-containing material 154 to form the graphene barrier 156, which surrounds the through via 182.

Referring to FIG. 26, in a step 408 of the method 400, the conductive feature is formed. Referring to FIG. 30, the carbon-containing material 154 (see FIG. 29) is removed, followed by forming a second conductive member 194 that is connected to the through via 182. In some embodiments, the second conductive member 194 may be surrounded by a second conductive barrier/liner 196. In some embodiments, the first conductive member 190 and the second conductive member 194 may be formed in a fourth dielectric layer 199 and may constitute the conductive feature 132. In some embodiments, the conductive feature 132 may include additional conductive members disposed over the second conductive member 194 and not shown in the figure. In some embodiments, the through via 182 may be connected to the first conductive member 190.

Referring to FIG. 26, in a step 410 of the method 400, the thickness of the substrate of the semiconductor structure is reduced. In a step 412 of the method 400, a plurality of the vias are formed. In a step 414 of the method 400, a plurality of the conductive structures are formed to obtain the conductive device 100 (see FIG. 31). Referring to FIGS. 30 and 31, after the thickness of the substrate 102 of the semiconductor structure 101 is reduced to a suitable value, the vias 160 are formed to be respectively connected to the epitaxial structures 114 as shown in FIG. 31, which is followed by forming the conductive structures 166 that are connected to the through via 182 and the vias 160. In some embodiments, the conductive structures 166 may be formed in a fifth dielectric layer 197. The number and position of the vias 160 and the conductive structures 166 may be changed according to practical requirements.

Deferring to FIG. 31, in some embodiments, the through via 182 may have a width (W3) ranging from about 40 nm to about 160 nm, from about 40 nm to about 50 nm, from about 50 nm to about 60 urn, from about 60 urn to about 70 nm, from about 70 nm to about 80 nm, from about 80 nm to about 90 nm, from about 90 nm to about 100 nm, from about 100 nm to about 110 nm, from about 110 nm to about 120 nm, from about 120 nm to about 130 nm, from about 130 nm to about 140 nm, from about 140 nm to about 150 nm, from about 150 nm to about 160 nm, or may be in other suitable ranges. In some embodiments, if the width (W3) of the through via 182 is too small, such as smaller than about 40 nm, defects (e.g., voids) may be formed in the through via 182, In some embodiments, if the width (W3) of the through via 182 is too large, such as greater than about 160 nm, the through via 182 may occupy a large area, reducing routing density of the semiconductor device 100. In some embodiments, the through via 182 may have a depth (D3) ranging from about 50 nm to about 400 nm, from about 50 nm to about 60 nm, from about 60 nm to about 70 nm, from about 70 nm to about 80 nm, from about 80 nm to about 90 nm, from about 90 nm to about 100 nm, from about 100 urn to about 110 nm, from about 110 nm to about 120 urn, from about 120 nm to about 130 nm, from about 130 nm to about 140 nm, from about 140 nm to about 150 nm, from about 150 nm to about 160 nm; from about 160 nm to about 170 nm; from about 170 nm to about 180 nm, from about 180 nm to about 190 nm, from about 190 nm to about 200 urn, from about 200 nm to about 210 urn, from about 210 nm to about 220 urn, from about 220 nm to about 230 run, from about 230 nm to about 240 nm, from about 240 nm to about 250 nm, from about 250 nm to about 260 nm, from about 260 nm to about 270 nm, from about 270 nm to about 280 nm, from about 280 nm to about 290 nm, from about 290 urn to about 300 nm, from about 300 nm to about 310 nm, from about 310 nm to about 320 nm, from about 320 nm to about 330 nm; from about 330 nm to about 340 nm, from about 340 nm to about 350 nm, from about 350 urn to about 360 nm, from about 360 nm to about 370 nm, from about 370 nm to about 380 nm, from about 380 urn to about 390 nm, from about 390 nm to about 400 nm, or may be in other suitable ranges. In some embodiments, if the depth (D3) of the through via 182 is too small, such as smaller than about 50 nm, the height of the epitaxial structures 114 may need to be decreased, adversely affecting electric properties of the semiconductor device 100. In some embodiments, if the depth (D3) of the through via 182 is too large, such as greater than about 400 nm, defects (e.g., voids) may be formed in the through via 182.

In accordance with some embodiments of the present disclosure, a semiconductor device includes a substrate, a plurality of channel layers, two epitaxial structures, a conductive structure, a via, and a graphene barrier. The channel layers are disposed over the substrate. The epitaxial structures are disposed over the substrate. The channel layers are connected between the epitaxial structures. The conductive structure is disposed on the substrate opposite to the epitaxial structures. The via is connected between one of the epitaxial structures and the conductive structure. The graphene barrier surrounds the via.

In accordance with some embodiments of the present disclosure, the graphene barrier is connected between the one of the epitaxial structures and the via.

In accordance with some embodiments of the present disclosure, the semiconductor device further includes a silicide feature that is connected between the one of the epitaxial structures and the graphene barrier.

In accordance with some embodiments of the present disclosure, the via includes a first surface that is connected to the one of the epitaxial structures, and a second surface that is opposite to the first surface and that is connected to the conductive structure. The graphene barrier covers the first surface and is disposed outside of the second surface.

In accordance with some embodiments of the present disclosure, the semiconductor device further includes a silicide feature that is connected to the one of the epitaxial structures and that is connected to a portion of the graphene barrier which covers the first surface.

In accordance with some embodiments of the present disclosure, the graphene barrier has a thickness ranging from about 1 Å to about 20 Å.

In accordance with some embodiments of the present disclosure, the graphene barrier includes pure graphene, graphene oxide, graphene nitride, or intercalated graphene.

In accordance with some embodiments of the present disclosure, the semiconductor device further includes a source/drain contact that is connected between the one of the epitaxial structures and the via.

In accordance with some embodiments of the present disclosure, the via includes a first surface that is connected to the source/drain, a second surface that is opposite to the first surface and that is connected to the conductive structure, and a side surface that is connected between the first and second surfaces.

In accordance with some embodiments of the present disclosure, the source/drain contact and the conductive structure are disposed opposite to each other relative to the epitaxial structures.

In accordance with some embodiments of the present disclosure, the via has a width ranging from about 5 nm to about 100 nm, and a depth ranging from about 10 nm to about 300 nm.

In accordance with some embodiments of the present disclosure, a semiconductor device includes a substrate, a plurality of channel layers, two epitaxial structures, a conductive feature, a conductive structure, a through via, and a graphene barrier. The channel layers are disposed over the substrate. The epitaxial structures are disposed over the substrate. The channel layers are connected between the epitaxial structures. The conductive feature is disposed over the epitaxial structures. The conductive structure is disposed on the substrate opposite to the conductive feature. The through via is connected between the conductive feature and the conductive structure. The graphene barrier surrounds the through via.

In accordance with some embodiments of the present disclosure, the through via includes a first surface that is connected to the conductive feature, a second surface that is opposite to the first surface and that is connected to the conductive structure, and a side surface that is connected between the first and second surfaces. The graphene barrier covers the side surface and is disposed outside of the first and second surfaces.

In accordance with some embodiments of the present disclosure, the semiconductor device further includes an isolation feature, and two gate electrodes that are separated from each other by the isolation feature. The through via penetrates the isolation feature.

In accordance with some embodiments of the present disclosure, the graphene barrier has a thickness ranging from about 1 Å to about 20 Å.

In accordance with some embodiments of the present disclosure, the graphene barrier includes pure graphene, graphene oxide, graphene nitride, or intercalated graphene.

In accordance with some embodiments of the present disclosure, the semiconductor device further includes a via that is connected between one of the epitaxial structures and the conductive structure.

In accordance with some embodiments of the present disclosure, the through via has a width ranging from about 40 nm to about 160 nm, and a depth ranging from about 50 nm to about 400 nm.

In accordance with some embodiments of the present disclosure, a method of forming a semiconductor device includes: forming a semiconductor structure that includes a substrate, a plurality of channel layers that are disposed over the substrate, two epitaxial structures that are disposed over the substrate, the channel layers being connected between the epitaxial structures; forming a recess in the substrate to expose a surface of one of the epitaxial structures; forming a silicide feature on the surface of the one of the epitaxial structures; forming a via in the recess and forming a graphene barrier that surrounds the via and that is connected between the via and the silicide feature; and forming a conductive structure that is disposed on the substrate and that is connected to the via.

In accordance with some embodiments of the present disclosure, the step of forming the via and forming the graphene barrier includes: forming a filling conductive layer on the substrate and in the recess; forming a carbon-containing material on the filling conductive layer; forcing carbon atoms of the carbon-containing material to diffuse through the filling conductive layer to form the graphene barrier; and removing a part of the filling conductive layer to form the via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein.

Those skilled in the art should also realize that such equivalent constructions do not depart from the spirit and scope of the present disclosure, and that they may make various changes, substitutions, and alterations herein without departing from the spirit and scope of the present disclosure,

What is claimed is:

1. A semiconductor device comprising:
a substrate;
a plurality of channel layers that are disposed over the substrate;
two epitaxial structures that are disposed over the substrate, the channel layers being connected between the epitaxial structures;
a conductive structure that is disposed on the substrate opposite to the epitaxial structures;
a via that is connected between one of the epitaxial structures and the conductive structure; and
a graphene barrier that surrounds the via.

2. The semiconductor device as claimed in claim 1; wherein the graphene barrier is connected between the one of the epitaxial structures and the via.

3. The semiconductor device as claimed in claim 2, further comprising a silicide feature that is connected between the one of the epitaxial structures and the graphene barrier.

4. The semiconductor device as claimed in claim 1, wherein:
the via includes a first surface that is connected to the one of the epitaxial structures, and a second surface that is opposite to the first surface and that is connected to the conductive structure; and
the graphene barrier covers the first surface and is disposed outside of the second surface.

5. The semiconductor device as claimed in claim 4, further comprising a silicide feature that is connected to the one of the epitaxial structures and that is connected to a portion of the graphene barrier which covers the first surface.

6. The semiconductor device as claimed in claim 1, wherein the graphene barrier has a thickness ranging from about 1 Å to about 20 Å.

7. The semiconductor device as claimed in claim 1, wherein the graphene barrier includes pure graphene, graphene oxide, graphene nitride, or intercalated graphene.

8. The semiconductor device as claimed in claim 1, further comprising a source/drain contact that is connected between the one of the epitaxial structures and the via.

9. The semiconductor device as claimed in claim 8, wherein:
the via includes a first surface that is connected to the source/drain contact, a second surface that is opposite to the first surface and that is connected to the conductive structure, and a side surface that is connected between the first and second surfaces; and
the graphene barrier covers the side surface and is disposed outside of the first and second surfaces.

10. The semiconductor device as claimed in claim 8, wherein the source/drain contact and the conductive structure are disposed opposite to each other relative to the epitaxial structures.

11. The semiconductor device as claimed in claim 1, wherein the via has a width ranging from about 5 nm to about 100 nm, and a depth ranging from about 10 nm to about 300 nm.

12. A semiconductor device comprising:
a substrate;
a plurality of channel layers that are disposed over the substrate;
two epitaxial structures that are disposed over the substrate, the channel layers are connected between the epitaxial structures;
a conductive feature that is disposed over the epitaxial structures;
a conductive structure that is disposed on the substrate opposite to the conductive feature;
a through via that is connected between the conductive feature and the conductive structure; and
a graphene barrier that surrounds the through via.

13. The semiconductor device as claimed in claim 12, wherein:
the through via includes a first surface that is connected to the conductive feature, a second surface that is opposite to the first surface and that is connected to the conductive structure, and a side surface that is connected between the first and second surfaces; and
the graphene barrier covers the side surface and is disposed outside of the first and second surfaces.

14. The semiconductor device as claimed in claim 12, further comprising an isolation feature, and two gate electrodes that are separated from each other by the isolation feature, the through via penetrating the isolation feature.

15. The semiconductor device as claimed in claim 12, wherein the graphene barrier has a thickness ranging from about 1 Å to about 20 Å.

16. The semiconductor device as claimed in claim 12, wherein the graphene barrier includes pure graphene, graphene oxide, graphene nitride, or intercalated graphene.

17. The semiconductor device as claimed in claim 12, further comprising a via that is connected between one of the epitaxial structures and the conductive structure.

18. The semiconductor device as claimed in claim 12, wherein the through via has a width ranging from about 40 nm to about 160 nm, and a depth ranging from about 50 nm to about 400 nm.

19. A method of forming a semiconductor device comprising:
forming a semiconductor structure that includes a substrate, a plurality of channel layers that are disposed over the substrate, two epitaxial structures that are disposed over the substrate, the channel layers being connected between the epitaxial structures;
forming a recess in the substrate to expose a surface of one of the epitaxial structures;
forming a silicide feature on the surface of the one of the epitaxial structures;
forming a via in the recess and forming a graphene barrier that surrounds the via and that is connected between the via and the silicide feature; and
forming a conductive structure that is disposed on the substrate and that is connected to the via.

20. The method as claimed in claim 19, wherein the step of forming the via and forming the graphene barrier includes: forming a filling conductive layer on the substrate and in the recess; forming a carbon-containing material on the filling conductive layer; forcing carbon atoms of the carbon-containing material to diffuse through the filling conductive layer to form the graphene barrier; and removing a part of the filling conductive layer to form the via.
